(19) United States
(12) Patent Application Publication
(10) Pub. No.: US 2005/0269581 A1
(43) Pub. Date: Dec. 8, 2005

(54) Light emitting diode light source

(75) Inventor: Joel M. Dry, Phoenix, AZ (US)

Correspondence Address: DONALD J. LENKSZUS, PO BOX 3064, CAREFREE, AZ, 85377, US

(73) Assignee: OPTOLUM, INC., Scottsdale, AZ (US)

(21) Appl. No.: 11/116,119

(22) Filed: Apr. 26, 2005

Related U.S. Application Data
(63) Continuation-in-part of application No. 10/984,366, filed on Nov. 8, 2004.
Application No. 10/984,366 is a continuation of application No. 10/430,732, filed on May 5, 2003, now Pat. No. 6,831,303.
Application No. 10/430,732 is a continuation of application No. 10/156,810, filed on May 29, 2002, now Pat. No. 6,573,536.

(51) Int. Cl. H01L 29/18

(52) U.S. Cl. 257/88

(57) ABSTRACT

A light or radiation emitting source that utilizes radiation emitting solid state or semiconductor devices is disclosed. The devices are mounted on a surface that is in thermal communication with a plurality of elongate thermally conductive members. The elongate thermally conductive members are utilized to cool the devices.

### RELATED APPLICATIONS

This application is a continuation-in-part of my co-pending application Ser. No. 10/984,366 filed Nov. 8, 2004 which is a continuation of application Ser. No. 10/430,732, filed May 5, 2003, now U.S. Pat. No. 6,831,303 issued Dec. 14, 2004 which is a continuation of application Ser. No. 10/156,810 filed May 29, 2002, now U.S. Pat. No. 6,573,536 issued Jun. 3, 2003.

### FIELD OF THE INVENTION

This invention pertains to lighting sources, in general, and to a lighting source that utilizes Light Emitting Diodes (LEDs), in particular.

### BACKGROUND OF THE INVENTION

LEDs have many advantages as light sources. However, in the past LEDs have found application only as specialized light sources such as for vehicle brake lights, and other vehicle related lighting, and recently as flashlights. In these prior applications, the LEDs are typically mounted in a planar fashion in a single plane that is disposed so as to be perpendicular to the viewing area. Typically the LED planar array is not used to provide illumination, but to provide signaling.

Recent attempts to provide LED light sources as sources of illumination have been few, and generally unsatisfactory from a general lighting standpoint.

It is highly desirable to provide a light source utilizing LEDs that provides sufficient light output so as to be used as a general lighting source rather than as a signaling source.

One problem that has limited the use of LEDs to specialty signaling and limited general illumination sources is that LEDs typically generate significant amounts of heat. The heat is such that unless the heat is dissipated, the LED internal temperature will rise causing degradation or destruction of the LED.

It is therefore further desirable to provide an LED light source that efficiently conducts heat away from the LEDs.

### SUMMARY OF THE INVENTION

In accordance with the principles of the invention, improved light sources are provided. One light source includes an elongate thermally conductive member having an outer surface. A plurality of light emitting diodes is carried on the elongate member outer surface. At least some of the light emitting diodes are disposed in a first plane and others of said light emitting diodes are disposed in a second plane not coextensive with the first plane. Electrical conductors are carried by the elongate thermally conductive member and are connected to the plurality of light emitting diodes to supply electrical power thereto. The elongate thermally conductive member conducts heat away from the light emitting diodes.

In accordance with one aspect of the invention, an illustrative embodiment of the invention utilizes light emitting diodes that emit white light. However, other embodiments of the invention may utilize light emitting diodes that are of different colors to produce monochromatic light or the colors may be chosen to produce white light or other colors.

In accordance with another aspect of the invention the elongate thermally conductive member transfers heat from the light emitting diodes to a medium within said elongate thermally conductive member. In the illustrative embodiment of the invention, the medium is air.

In accordance with another aspect of the invention, the elongate thermally conductive member has one or more fins to enhance heat transfer to the medium.

In accordance with another aspect of the invention the elongate thermally conductive member comprises a tube. In one embodiment of the invention, the tube has a cross-section in the shape of a polygon. In another embodiment of the invention, the tube has a cross-section having flat portions.

In accordance with another embodiment of the invention, the elongate thermally conductive member comprises a channel.

In accordance with the principles of the invention, the elongate thermally conductive member may comprise an extrusion, and the extrusion can be highly thermally conductive material such as aluminum.

In one preferred embodiment of the invention the elongate thermally conductive member is a tubular member. The tubular member has a polygon cross-section. However, other embodiments my have a tubular member of triangular cross-section.

In one embodiment of the invention, a flexible circuit is carried on a surface of said elongate thermally conductive member; the flexible circuit includes the electrical conductors.

In another aspect of the invention, the flexible circuit comprises a plurality of apertures for receiving said plurality of light emitting diodes. Each of the light emitting diodes is disposed in a corresponding one of the apertures and affixed in thermally conductive contact with said elongate thermally conductive member.

The elongate thermally conductive member includes a thermal transfer media disposed therein in a flow channel.

At least one clip for mounting the elongate thermally conductive member in a fixture may be included.

Another light source in accordance with the principles of the invention includes a plurality of elongate thermally conductive members. A surface is in thermal communication with said plurality of elongate thermally conductive members. At least one light emitting diode is carried on the surface and in thermal communication therewith. One or more electrical conductors are carried by the surface and connected to the at least one light emitting diode to supply electrical power thereto.

In accordance with the principles of the invention, the plurality of elongate thermally conductive members are configured to conduct heat away from the at least one light emitting diode to fluid contained by the plurality of elongate thermally conductive members.

In an embodiment of the invention, a circuit board is disposed between the at least one light emitting diode and the surface. The circuit board comprises one thermally conductive surface proximate the at least one light emitting diode and a second thermally conductive surface proximate said one surface and in thermal communication therewith. The circuit board comprising a plurality of thermally conductive conduits extending from the one surface to the second surface to provide thermal coupling between the one surface and the second surface.

In accordance with one aspect of the invention, the light source includes a lens structure or a reflector structure disposed above said at least one light emitting diode. In the illustrative embodiment of the invention, the lens structure or the reflector structure comprises plastic.

### BRIEF DESCRIPTION OF THE DRAWING

The invention will be better understood from a reading of the following detailed description of a preferred embodiment of the invention taken in conjunction with the drawing figures, in which like reference indications identify like elements, and in which:

FIG. 1 is a planar side view of a light source in accordance with the principles of the invention;

FIG. 2 is a top planar view of the light source of FIG. 1;

FIG. 3 is a perspective view of the light source of FIG. 1 with mounting clips;

FIG. 4 is a planar side view of the light source of FIG. 3 showing mounting clips separated from the light source;

FIG. 5 is a top view of the light source and mounting clips of FIG. 4;

FIG. 6 is a partial cross-section of the light source of FIG. 1;

FIG. 7 is a top view of a second light source in accordance with the principles of the invention;

FIG. 8 is a side planar view of the light source of FIG. 7;

FIG. 9 is an exploded perspective view of the light source of FIGS. 7 and 8;

FIG. 10 is a partially exploded perspective view of a portion of the light source of FIGS. 7 and 8;

FIG. 11 is a top view of a circuit board portion of the light source of FIGS. 7 and 8;

FIG. 12 is a top planar view of a portion of the circuit board of FIGS. 7 and 8;

FIG. 13 is a bottom view of the circuit board of FIG. 11;

FIG. 14 is a planar view of a faceplate utilized to mount a plurality of light sources of the type shown in FIGS. 7 and 8;

FIG. 15 is a detail of a portion of the faceplate of FIG. 14; and

FIG. 16 illustrates the faceplate of FIG. 14 with a plurality of light sources mounted thereto.

### DETAILED DESCRIPTION

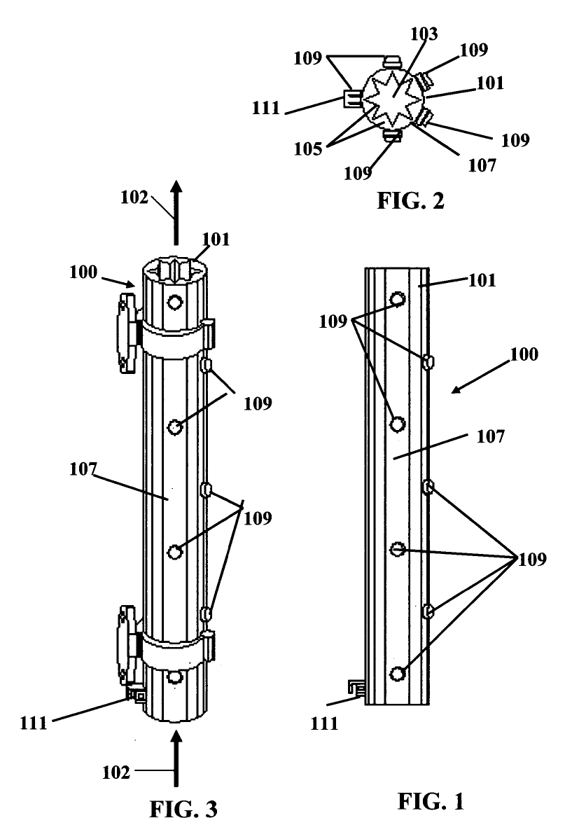

A light source in accordance with the principles of the invention may be used as a decorative lighting element or may be utilized as a general illumination device. As shown in FIG. 1, a light source 100 in accordance with the invention includes an elongate thermally conductive member or heat sink 101. Elongate heat sink 101 is formed of a material that provides excellent thermal conductivity. Elongate heat sink 101 in the illustrative embodiment of the invention is a tubular aluminum extrusion. To improve the heat dissipative properties of light source 100, elongate heat sink 101 is configured to provide convective heat dissipation and cooling. As more clearly seen in FIG. 2, tubular heat sink 101 is hollow and has an interior cavity 103 that includes one or more heat dissipating fins 105. Fins 105 are shown as being triangular in shape, but may take on other shapes. Fins 105 are integrally formed on the interior of elongate heat sink 101. In the illustrative embodiment convective cooling is provided by movement of a medium 102 through elongate heat sink 101. The medium utilized in the illustrative embodiment is air, but may in some applications be a fluid other than air to provide for greater heat dissipation and cooling

The exterior surface 107 of elongate heat sink 101 has a plurality of Light Emitting Diodes 109 disposed thereon. Each LED 109 in the illustrative embodiment comprises a white light emitting LED of a type that provides a high light output. Each LED 109 also generates significant amount of heat that must be dissipated to avoid thermal destruction of the LED. By combining a plurality of LEDs 109 on elongate heat sink 101, a high light output light source that may be used for general lighting is provided.

Conductive paths 129 are provided to connect LEDs 109 to an electrical connector 111. The conductive paths may be disposed on an electrically insulating layer 131 or layers disposed on exterior surface 107. In the illustrative embodiment shown in the drawing figures, the conductive paths and insulating layer are provided by means of one or more flexible printed circuits 113 that are permanently disposed on surface 107. As more easily seen in FIG. 6, printed circuit 113 includes an electrically insulating layer 131 that carries conductive paths 129. As will be appreciated by those skilled in the art, other means of providing the electrically conductive paths on the

Flexible printed circuit 113 has LEDs 109 mounted to it in a variety of orientations ranging from 360 degrees to 180 degrees and possibly others depending on the application. Electrical connector 111 is disposed at one end of printed circuit 113. Connector 113 is coupleable to a separate power supply to receive electrical current. Flexible printed circuit 113, in the illustrative embodiment is coated with a non-electrically conductive epoxy that may be infused with optically reflective materials. Flexible printed circuit 113 is adhered to the tube 101 with a heat conducting epoxy to aid in the transmission of the heat from LEDs 109 to tube 101. Flexible printed circuit 113 has mounting holes 134 for receiving LEDs 109 such that the backs of LEDs 109 are in thermal contact with the tube surface 107.

Tubular heat sink 101 in the illustrative embodiment is formed in the shape of a polygon and may have any number of sides. Although tubular heat sink 101 in the illustrative embodiment is extruded aluminum, tubular heat sink 101 may comprise other thermal conductive material. Fins 105 may vary in number and location depending on particular LED layouts and wattage. In some instances, fins may be added to the exterior surface of tubular heat sink 101. In addition, apertures may be added to the tubular heat sink to enhance heat flow.

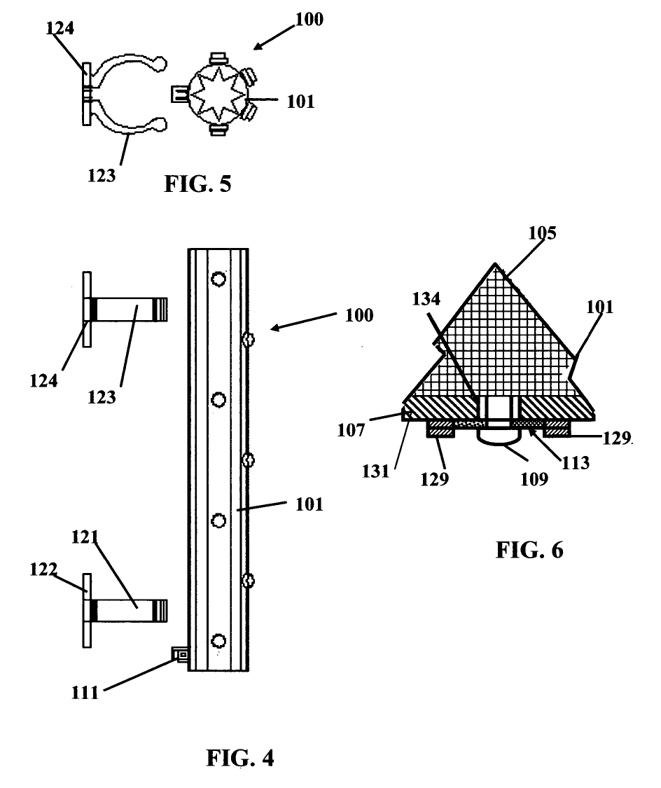

Light source 100 is mounted into a fixture and retained in position by mounting clips 121,123 as most clearly seen in FIGS. 3, 4, and 5. Each of the clips is shaped so as to engage and retain light source 100. Each clip is affixed on one surface 122, 124 to a light fixture.

Although light source 100 is shown as comprising an elongate tubular heat sink, other extruded elongate members may be used such as channels.

In the illustrative embodiment shown, convection cooling by flow of air through tubular heat sink 101 is utilized such that cool or unheated air enters tubular heat sink 101 at its lower end and exits from the upper end as heated air. In higher wattage light sources, rather than utilizing air as the cooling medium, other fluids may be utilized. In particular, convective heat pumping may be used to remove heat from the interior of the heat sink.

In one particularly advantageous embodiment of the invention, the light source of the invention is configured to replace compact fluorescent lighting in decorative applications.

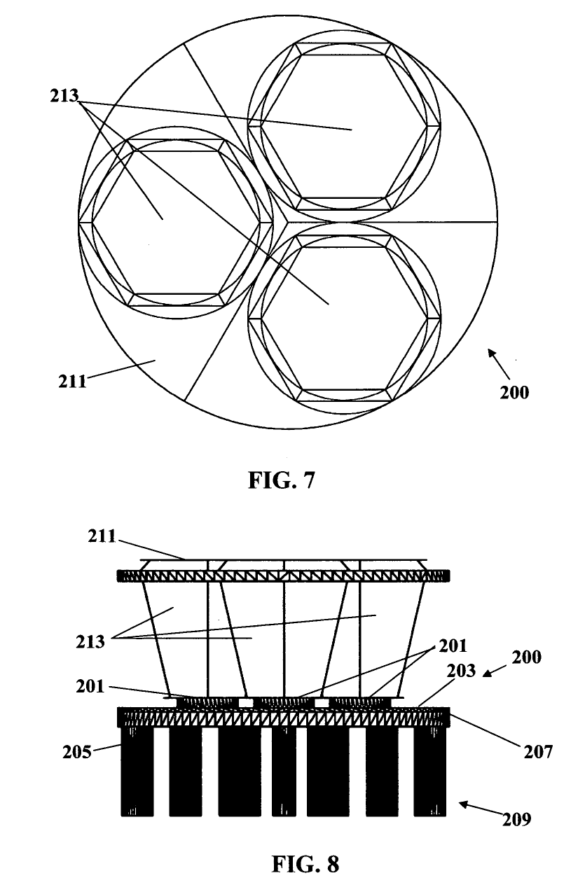

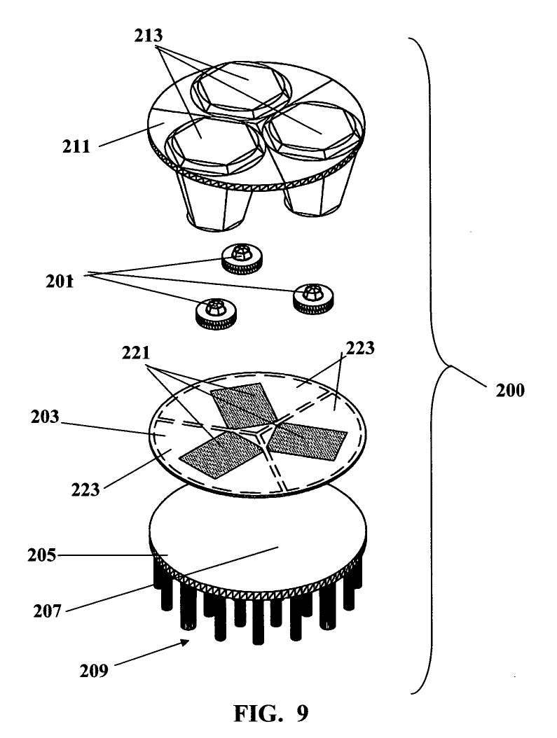

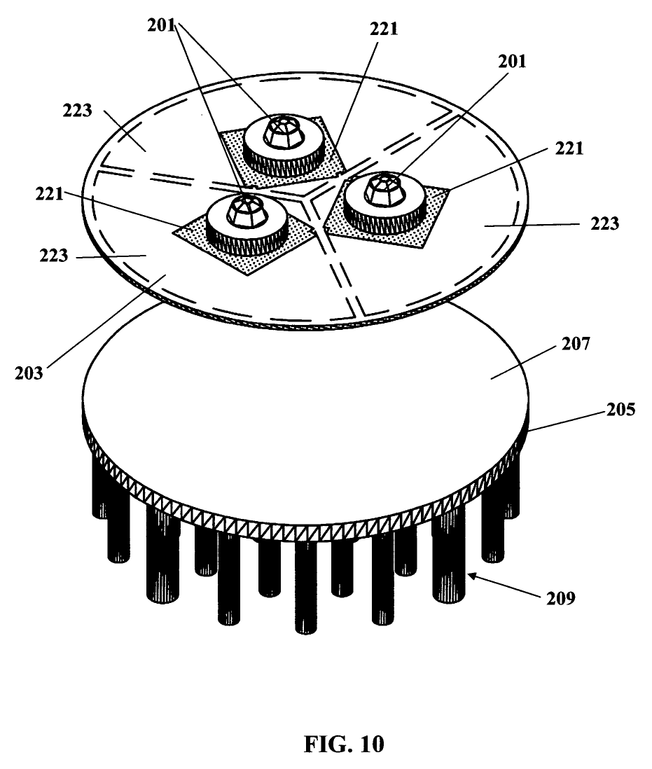

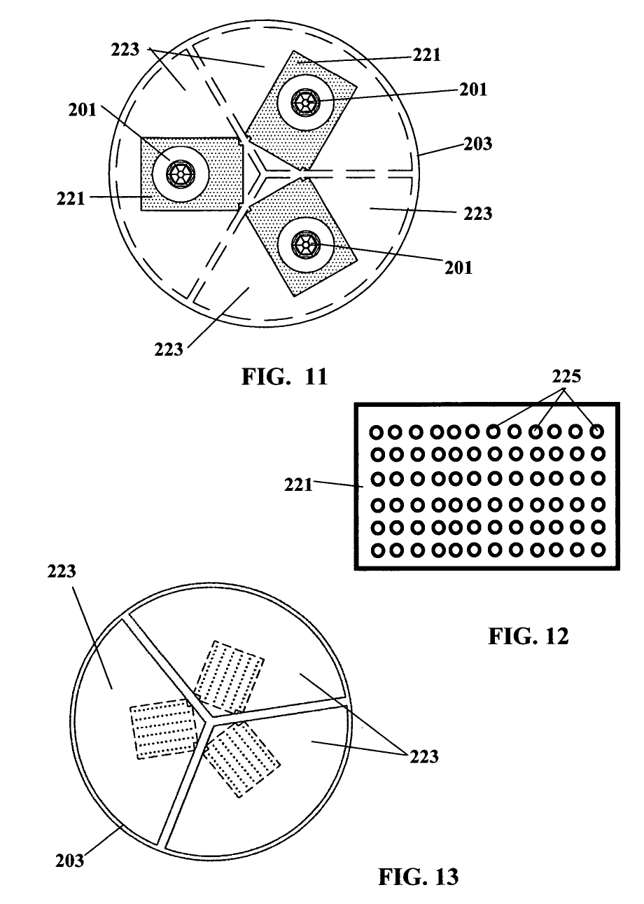

Turning now to FIGS. 7 through 13, inclusive, a second light source 200 in accordance with the principles of the invention is shown. Light source 200 comprises at least one LED 201, and more specifically in the embodiment shown comprise three LEDs 201. Each LED 201 is carried on a surface 207 of a heat transfer member or heat sink 205 having a plurality of elongate thermally conductive members 209. Surface 207 is in thermal communication with the plurality of elongate thermally conductive members 209. In the embodiment shown, member 205 is fabricated from aluminum or other material having excellent heat transfer properties. The elongate thermally conductive members 209 are configured to transfer heat to fluid that is contained by or surrounding the thermally conductive members 209.

Surface 207 carries LEDs 201 via an electrically insulating layer or intermediate circuit board 203. Layer or circuit board 203 has a thermally conductive or metallic portion 221 for each LED 201 on one surface of board 203. Each LED 201 is affixed to and in thermal communication with its corresponding thermally conductive portion 221. On the second or other side of layer or circuit board 203, corresponding thermally conductive or metallic portions 223 are provided. Each portion 221 is in thermal communication with its corresponding portion 223 via pluralities of apertures or conduits 225 through circuit board 203. In the embodiment of the invention shown, each aperture 225 is filled with thermally conductive material such that each portion 221 is in thermal communication with its corresponding portion 223 via filled apertures or conduits 225.

Layer or circuit board 203 has formed thereon conductors for providing power to LEDs 201. The electrical conductors formed on layer or circuit board 203 may be metal traces or paths formed in any manner known in the art. Similarly, thermally conductive portions 221 and 223 may be metal layers formed on circuit boards in any manner known in the art. Apertures or conduits 225 may be solder filled as is commonly done in the printed circuit arts or alternatively may be of other thermally conductive material such that the portions 221 are in thermal communication with portions 223.

As will be evident to those skilled in the art, the shapes of the thermally conductive portions 221 and 223 are not limited in any way to the shapes shown in the drawings and may have other configurations. In addition, as will be appreciated by those skilled in the art, although multiple portions 221 are shown, one or more thermally conductive portions may be provided. Similarly, one or more thermally conductive portions 223 may be provided.

Light source 200 also includes a light director 211. Light director 211 acts as a lens or reflector to direct light from each LED 201 in a desired direction. Light director 211, in the illustrative embodiment, comprises a plurality of light directors 213 that are integrally formed as a unit. The unitary light director 211 is formed of plastic in the illustrative embodiment, but may be formed of other materials. In the illustrative embodiment, each of the light directors is a lens, but may also be a reflector or a combination lens and reflector. Light director 211 is affixed to circuit board 203 and heat sink 205 such that light source 200 is a modular light source.

It will be apparent to those skilled in the art that modular light source 200 may have a wiring harness, a lightbulb type base, a pin type connector or may have terminal blocks, depending on the specific application.

It will also be apprarent to those skilled in the art that layer or circuit board 203 may be a metal core circuit board, a flexible circuit board, or a polyamide layer that can be laminated directly to a metal extrusion.

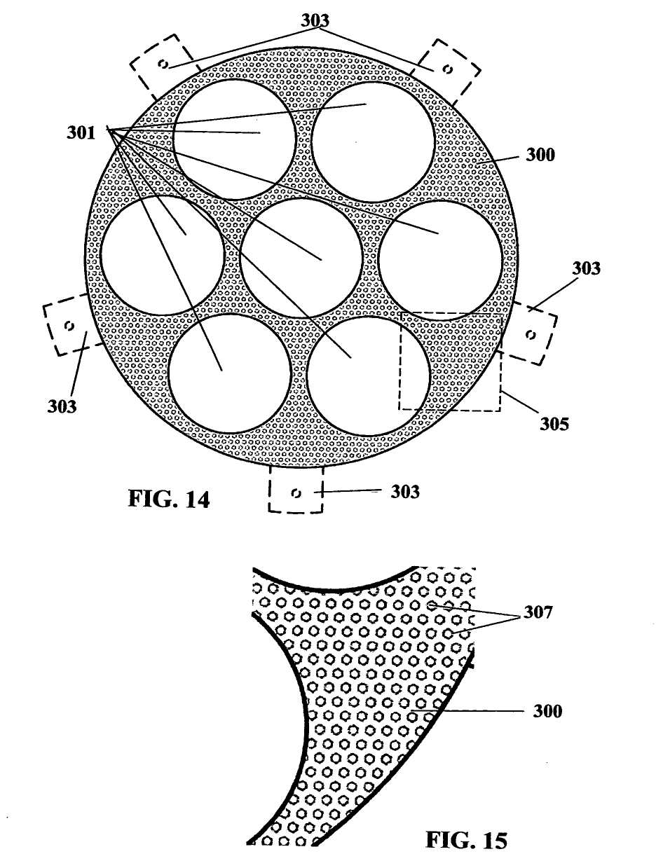

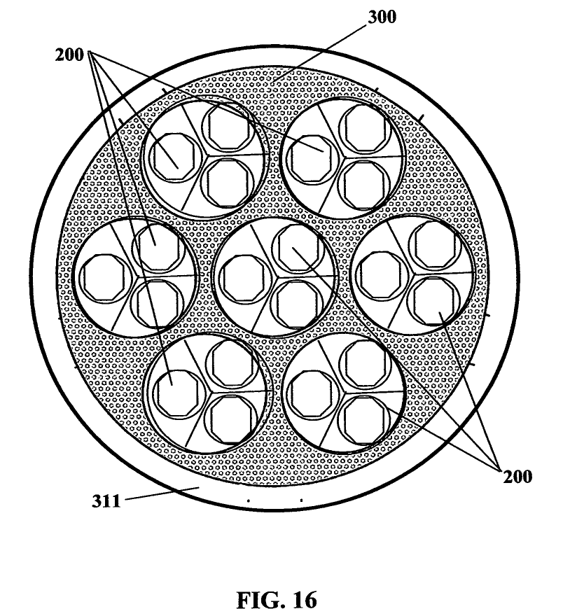

Turning now to FIGS. 14-16, a faceplate 300 is shown which may advantageously be utilized in combination with light source 200 to provide a replacement retrofit for existing fixtures. Faceplate 300 is shown with seven light source module receiving openings 301, each of which receives one light source 200. It will be understood by those skilled in the art, that faceplate 300 may be configured to have any number of light source module receiving openings depending on the size of the existing fixture and the light output desired. Faceplate 300 is formed from perforated metal and is stamped notched and shaped to allow for attachment of light source modules 200 and fixtures. By providing perforations or apertures 307 that are more clearly seen in FIG. 15 which is an enlargement of portion 305 of FIG. 14, heat transfer to the ambient air from air in the fixture is facilitated. As shown in FIG. 14, Faceplate 300 may have a plurality of flanges or clips 303 to facilitate mounting in a fixture. In addition, a trim ring or mounting ring 311 may be provided.

As will be appreciated by those skilled in the art, the principles of the invention are not limited to the use of light emitting diodes that emit white light. Different colored light emitting diodes may be used to produce monochromatic light or to produce light that is the combination of different colors. In addition, the principles of the invention further are advantageously applied to other types of solid state light sources and radiation emitting semiconductor devices.

Although the invention has been described in terms of illustrative embodiments, it is not intended that the invention be limited to the illustrative embodiments shown and described. It will be apparent to those skilled in the art that various changes and modifications may be made to the embodiments shown and described without departing from the spirit or scope of the invention. It is intended that the invention be limited only by the claims appended hereto.

1. A light source comprising:
a plurality of elongate thermally conductive members;
a surface in thermal communication with said plurality of elongate thermally conductive members;
at least one light emitting diode carried on said surface and in thermal communication therewith;
one or more electrical conductors carried by said surface and connected to said at least one light emitting diode to supply electrical power thereto.

2. A light source in accordance with claim 1, comprising:
a layer carrying said surface;
said layer comprising one or more thermally conductive paths between said surface and said elongate thermally conductive members.

3. A light source in accordance with claim 2, comprising:
said layer comprises one or more of metallic paths extending from said surface and in thermal communication with said elongate thermally conductive members.

4. A light source in accordance with claim 2, wherein:
said layer comprises a circuit board.

5. A light source in accordance with claim 2, wherein:
said layer comprises a polyamide layer.

6. A light source in accordance with claim 2, comprising:
a light director disposed proximate said at least one light emitting diode.

7. A light source in accordance with claim 6, wherein:
said light director comprises a lens structure disposed above said at least one light emitting diode.

8. A light source in accordance with claim 6, wherein;
said light director is a structure formed from plastic material.

9. A light source in accordance with claim 6, wherein:
said light director comprises a reflector structure disposed proximate said at least one light emitting diode.

10. A light source in accordance with claim 9, wherein:
said reflector structure comprises a reflector of plastic material.

11. A light source in accordance with claim 2, comprising:
said plurality of elongate thermally conductive members are configured to conduct heat away from said at least one light emitting diode to fluid contained by said plurality of elongate thermally conductive members.

12. A light source in accordance with claim 1, comprising:
said plurality of elongate thermally conductive members are configured to conduct heat away from said at least one light emitting diode to fluid contained by said plurality of elongate thermally conductive members.

13. A light module comprising:
a plurality of elongate thermally conductive members;
a surface in thermal communication with said plurality of elongate thermally conductive members;
a plurality of one light emitting diodes carried on said surface and in thermal communication therewith;
one or more electrical conductors carried by said surface and connected to said plurality of light emitting diodes to supply electrical power thereto.

14. A light source in accordance with claim 13, comprising:
a layer carrying said surface;
said layer comprising one or more thermally conductive paths between said surface and said elongate thermally conductive members.

15. A light source in accordance with claim 14, comprising:
said layer comprises one or more of metallic paths extending from said surface and in thermal communication with said elongate thermally conductive members.

16. A light source in accordance with claim 14, wherein:
said layer comprises a circuit board.

17. A light source in accordance with claim 14, wherein:
said layer comprises a polyamide layer.

18. A light source in accordance with claim 14, comprising:
a light director disposed proximate said plurality of light emitting diodes.

19. A light source in accordance with claim 18, wherein:
said light director comprises a lens structure disposed above said plurality of light emitting diodes.

20. A light source in accordance with claim 18, wherein;
said light director is a structure formed from plastic material.

21. A light source in accordance with claim 18 wherein:
said light director comprises a reflector structure disposed proximate said plurality of light emitting diodes.

22. A light source in accordance with claim 21, wherein:
said reflector structure comprises a reflector of plastic material.

23. A light source in accordance with claim 13, comprising:
said plurality of elongate thermally conductive members are configured to conduct heat away from said plurality of light emitting diodes to fluid contained by said plurality of elongate thermally conductive members.

24. Apparatus for use in a light fixture comprising:
a faceplate comprising perforated metal, said faceplate comprising one or more openings for receiving a corresponding one or more light source modules;
each light module comprising:
a plurality of elongate thermally conductive members;
a surface in thermal communication with said plurality of elongate thermally conductive members;
at least one light emitting diode carried on said surface and in thermal communication therewith;
one or more electrical conductors carried by said surface and connected to said at least one light emitting diode to supply electrical power thereto.
